(19) United States
(12) Patent Application Publication
(10) Pub. No.: US 2007/0096221 A1
(43) Pub. Date: May 3, 2007

(54) SEMICONDUCTOR DEVICE COMPRISING COPPER-BASED CONTACT PLUG AND A METHOD OF FORMING THE SAME

(76) Inventors: Kai Frohberg, Niederau (DE); Frank Koschinsky, Radebeul (DE); Katja Huy, Dresden (DE)

Correspondence Address: WILLIAMS, MORGAN & AMERSON, 10333 RICHMOND, SUITE 1100, HOUSTON, TX, 77042, US

(21) Appl. No.: 11/427,206

(22) Filed: Jun. 28, 2006

(30) Foreign Application Priority Data
Oct. 31, 2005 (DE) 10 2005 052 001.4

(51) Int. Cl. H01L 23/52; H01L 21/44

(52) U.S. Cl. 257/383; 438/687; 438/656; 257/762; 257/763

(57) ABSTRACT

By providing a tungsten nitride barrier layer for a contact plug, well-approved copper-based via formation techniques may be used to form a highly conductive contact plug, thereby significantly reducing the series resistance compared to conventional tungsten-based contact plugs. The tungsten nitride barrier layer may be deposited by ALD techniques, which exhibit superior step coverage and thus allow a reliable coverage of exposed surfaces of the contact opening, thereby providing the potential for using copper or copper alloys even in the vicinity of highly sensitive device areas of circuit elements, such as transistors and the like.

### BACKGROUND OF THE INVENTION

1. Field of the Invention

The present invention relates to the field of semiconductor manufacturing, and, more particularly, to the formation of an interconnect structure having a contact plug for directly contacting a circuit element.

2. Description of the Related Art

During the process of manufacturing sophisticated semiconductor devices, such as modern CPUs, a plurality of different material layers are deposited on each other and patterned to define required device features. In general, subsequent material layers should exhibit good adhesion to each other while at the same time maintaining the integrity of each individual layer, i.e., chemical reaction of adjacent layers and/or diffusion of atoms from one layer into the other layer should be avoided during the manufacturing processes for the fabrication of the individual layers and subsequent processes, as well as afterwards when operating the completed device. To meet these requirements, an intermediate layer is often required to provide good adhesion and to suppress diffusion and thus undue interference between neighboring materials during processing and operation. A typical example for such requirements in the fabrication of semiconductor devices is the formation of interconnect plugs, wherein openings and trenches having a bottom region and a sidewall region have to be provided with a corresponding intermediate layer, that is, a conductive barrier layer, so that a subsequently deposited conductive material exhibits good adhesion to the surrounding dielectric layer, and undue interaction during processing and operation may be avoided. In advanced semiconductor devices, the interconnect plugs are typically formed of a tungsten-based metal that are provided in an interlayer dielectric stack which is typically comprised of silicon dioxide including a bottom etch stop layer typically formed of silicon nitride.

In general, the electrical resistance of the barrier metal layer is significantly higher than the resistance of the tungsten-based material forming the contact plug, so that the thickness of the barrier metal layer is selected to be as small as possible in order to avoid an undue increase of the overall resistance of the contact plug.

In modern integrated circuits, openings (so-called vias) are formed exhibiting an aspect ratio that may be as high as approximately 8:1 or more, and the opening may have a diameter of 0.1 μm or smaller. The aspect ratio of such openings is generally defined as the ratio of the depth of the opening to the width of the opening. Accordingly, it is extremely difficult to form a thin, uniform barrier metal layer on the entire sidewalls, especially at the bottom corners, to effectively avoid direct contact of the metal with the surrounding dielectric material, i.e., it is difficult to form a barrier metal layer that adequately covers all surfaces of the openings.

With reference to FIG. 1, a typical conventional process for manufacturing contacts to a circuit device in accordance with a well-established tungsten technology will now be described in more detail in order to illustrate the problems involved in the formation of a reliable conductive barrier layer.

FIG. 1 schematically shows a semiconductor device 100 during a manufacturing stage for the formation of interconnect plugs providing a connection to a circuit element, such as a transistor 110, that is formed above an appropriate semiconductor substrate 101. The circuit element 110 may comprise one or more contact regions, such as a gate electrode 111 and drain and source regions 112. The circuit element 110 is covered by a dielectric material, which may comprise a contact etch stop layer 102, which may be formed of silicon nitride, and an interlayer dielectric material 103, which is typically silicon dioxide. Moreover, two contact openings 104A, 104B are formed within the dielectric layers 103 and 102 to connect to the respective contact regions 111 and 112. Furthermore, a conductive barrier layer, which is typically comprised of a titanium liner 105 and a titanium nitride layer 106 in a tungsten contact technology, is formed on the dielectric layer 103 and within the contact openings 104A, 104B. The titanium liner 105 and the titanium nitride barrier layer 106 may be formed to enhance the reliability of the subsequent deposition of a tungsten-based material, wherein the deposition process is typically performed as a chemical vapor deposition (CVD) process, in which tungsten hexafluorine (WF₆) is reduced in a thermally activated first step on the basis of silane (SiH₄) and is then, in a second step, converted into tungsten on the basis of hydrogen. During the reduction of the tungsten on the basis of hydrogen, a direct contact to the silicon dioxide of the dielectric layer 103 is substantially prevented by the titanium liner 105 in order to avoid undue silicon consumption from the silicon dioxide. However, titanium nitride exhibits a rather poor adhesion to silicon dioxide and may therefore jeopardize the reliability of the respective tungsten plug formed subsequently. Consequently, the titanium nitride barrier layer 106 is provided for improving adhesion of the titanium layer 105.

A typical process flow for forming the semiconductor device 100 as shown in FIG. 1 may comprise the following processes. After the formation of the circuit element 110 on the basis of well-established manufacturing techniques, the contact etch stop layer 102 may be formed on the basis of well-known plasma enhanced chemical vapor deposition (PECVD) techniques, followed by the deposition of the silicon dioxide of the layer 103 on the basis of TEOS, thereby providing a dense and compact material layer. After any optional planarization processes for planarizing the layer 103, a photolithography sequence may be performed on the basis of well-established recipes, followed by anisotropic etch techniques for forming the contact openings 104A, 104B in the layer 103, wherein the etch process may be reliably controlled on the basis of the etch stop layer 102. Thereafter, a further etch process may be performed to finally open the contact etch stop layer 102 on the basis of well-established techniques. Thereafter, the titanium liner 105 may be formed on the basis of ionized physical vapor deposition, such as sputter deposition. The term “sputtering” or “sputter deposition” describes a mechanism in which atoms are ejected from a surface of a target material upon being hit by sufficiently energetic particles. Sputtering has become a dominant technique for depositing titanium, titanium nitride and the like. Although, in principle, an improved step coverage could be obtained by using CVD techniques, sputter deposition is widely used for the deposition of the liner 105 for the following reasons.

Sputter deposition allows the relatively uniform deposition of layers over large area substrates, since sputtering can be accomplished from large-area targets. Control of film thickness by sputter deposition is relatively simple as compared to CVD deposition and may be achieved by selecting a constant set of operating conditions, wherein the deposition time is then adjusted to achieve the required film thickness. Moreover, the composition of compounds, such as titanium nitride used in the barrier layer 106, can be controlled more easily and precisely in sputter deposition processes as compared to CVD processes. Additionally, the surfaces of the substrates to be processed may be sputter-cleaned prior to the actual film deposition so that any contamination of the surface may be efficiently removed and further recontamination prior to the actual deposition process may be effectively suppressed. For an efficient deposition of a moderately thin material within the contact openings 104A, 104B having a moderately high aspect ratio, so-called ionized sputter deposition techniques are used, in which target atoms liberated from the target are efficiently ionized by a respective plasma ambient while moving towards the substrate. On the basis of a DC or RF bias, the directionality of the moving ionized target atoms may be significantly enhanced, thereby enabling the deposition of target material at the bottom of the contact openings 104A, 104B even for high aspect ratios.

Due to this mechanism, however, the layer thickness at the bottom 104C may be significantly thicker compared to a thickness at the sidewalls of the contact openings 104A, 104B, even though these sidewalls may be covered by a substantially continuous layer. In particular, at lower sidewall portions 104D, the corresponding layer thickness may be significantly thinner compared to the thickness at the bottom 104C. However, a reliable and thus minimum layer thickness may be required, especially at the bottom sidewall portions 104D, in order to substantially prevent any deleterious interaction during the subsequent tungsten deposition. For example, for a minimum layer thickness of approximately 50-60 Å at the lower sidewall portions 104D, a bottom layer thickness of approximately 300-400 Å may be required, thereby resulting in an increased contact resistivity, as the combination of titanium nitride and titanium exhibits a moderately high resistance compared to the contact regions 112 and the subsequently filled-in tungsten. Moreover, in sophisticated applications requiring the formation of high aspect ratio contact plugs, even the moderately low conductivity of the tungsten plug, compared to copper-based vias provided in higher metallization layers, may significantly contribute to a signal propagation delay, thereby restricting the operating speed of the entire integrated circuit. However, using the copper technology based on tantalum as barrier as applied for vias in the metallization layers may not suffice to reliably suppress copper diffusion into sensitive transistor areas as already minute holes in the tantalum may lead to the growth of copper silicide, thereby finally resulting in a transistor failure.

In view of the situation described above, there exists a need for an enhanced technique that enables the formation of reliable contact plugs with reduced contact resistance while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the formation of contact plugs in semiconductor devices, which directly connect to circuit elements, such as transistors, wherein a significantly reduced contact resistance is obtained by using a highly conductive material, such as a copper-containing metal. Moreover, the corresponding contact plugs may have an efficient conductive barrier layer comprising a tungsten-based layer, which may be deposited on the basis of highly conformal chemical vapor deposition (CVD) techniques, thereby ensuring an enhanced step coverage, even at critical regions of the contact openings. The tungsten-based material also exhibits a high copper diffusion blocking effect, thereby enabling the usage of well-approved copper metallization schemes, even for the highly sensitive device regions located next to the circuit elements. Consequently, compared to conventional techniques, which are based on a tungsten contact plug, even for highly scaled semiconductor devices, a significantly reduced resistance and thus an increased operating speed of the transistor elements may be achieved. Additionally, in illustrative embodiments, an atomic layer deposition (ALD) technique may be used, which is highly scaleable with respect to a further increase of the aspect ratio of corresponding contact openings, thereby providing the potential for forming extremely thin, yet highly reliable conductive barrier layers for extremely scaled semiconductor devices.

According to one illustrative embodiment of the present invention, a semiconductor device comprises a circuit element having a contact region. The semiconductor device further comprises a contact plug formed in a dielectric layer to connect to the contact region, wherein the contact plug comprises copper and a tungsten-containing barrier layer separating the dielectric layer and the copper.

According to another illustrative embodiment of the present invention, a method comprises forming a conductive barrier layer in a contact opening of a circuit element on the basis of a tungsten-containing precursor material. Moreover, the contact opening is then filled with a copper-containing material.

### BRIEF DESCRIPTION OF THE DRAWINGS

The invention may be understood by reference to the following description taken in conjunction with the accompanying drawings, in which like reference numerals identify like elements, and in which:

FIG. 1 schematically shows a cross-sectional view of a semiconductor device during the formation of contact plugs on the basis of a conventional tungsten technology; and

FIGS. 2a-2g schematically show cross-sectional views of a semiconductor device during the formation of contact plugs on the basis of a tungsten-containing conductive barrier layer and a copper-based fill material during various manufacturing stages in accordance with illustrative embodiments of the present invention.

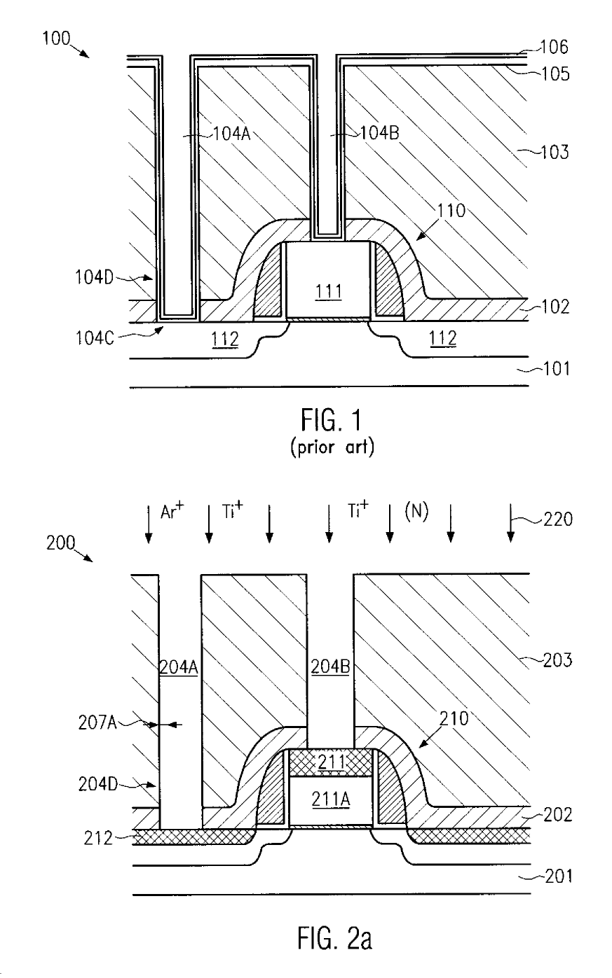

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention relates to an enhanced technique for the formation of contact plugs connecting to respective contact regions of circuit elements, such as transistors, capacitors and the like. For this purpose, a highly conductive material, such as copper, may be used in combination with a tungsten-based barrier material, which may be deposited in a highly reliable fashion, i.e., with an excellent step coverage, while on the other hand providing a high copper blocking capability, which may thus allow the usage of copper in the neighborhood of highly sensitive device regions. In some illustrative embodiments, the tungsten-based conductive barrier layer may be formed by advanced CVD techniques, such as atomic layer deposition (ALD) on the basis of appropriate precursor materials, wherein the excellent step coverage of the ALD process provides high reliability, even with a reduced layer thickness. Thus, based on the tungsten-containing barrier layer, copper metallization techniques, as may be typically used for the contact via and metal line formation in highly sophisticated copper-based metallization layers, may also be used in combination with the formation of contact plugs, thereby significantly enhancing the thermal and electrical conductivity of the respective contacts. Consequently, the technique of the present invention may be readily extended to the fabrication of contact structures of even highly scaled semiconductor devices, which may have critical dimensions of 100 nm and even significantly less.

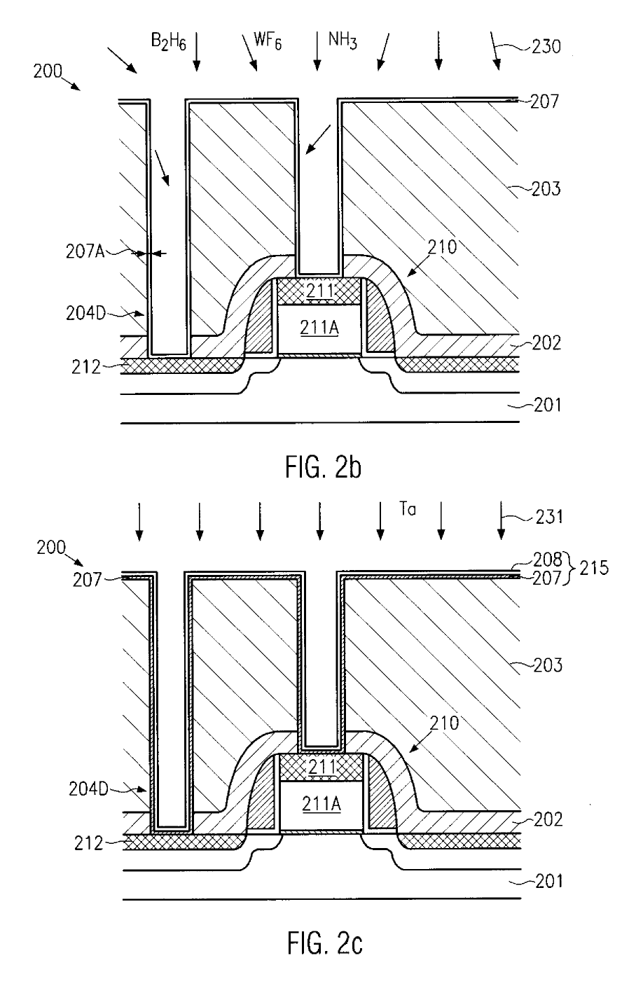

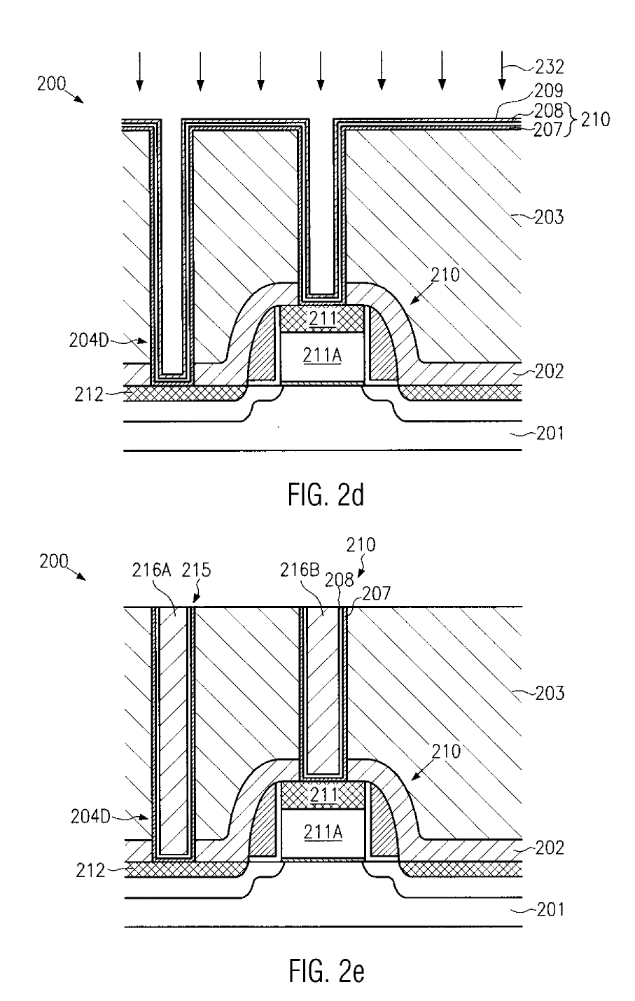

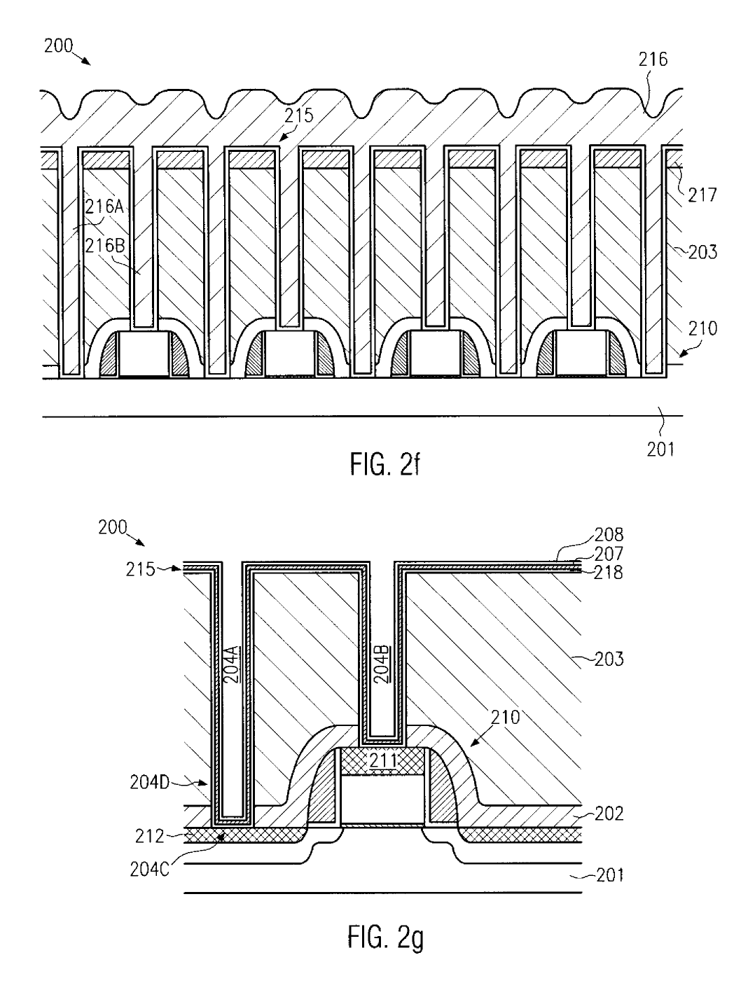

With reference to FIGS. 2a-2g, further illustrative embodiments of the present invention will now be described in more detail. FIG. 2a schematically shows a semiconductor device 200 that comprises a circuit element 210, such as a capacitor, a resistor or any other circuit element, which, in one illustrative embodiment, may represent a transistor element that is formed above a substrate 201. The substrate 201 may represent any appropriate substrate for forming semiconductor devices thereon, such as a silicon-on-insulator (SOI) substrate, a bulk semiconductor substrate, or any other appropriate carrier having formed thereon a suitable semiconductor layer for forming circuit devices thereon and therein. The circuit element 210 may comprise one or more contact regions 211, 212, which in the example shown are represented by a gate electrode, i.e., the contact region 211, and drain and source regions, i.e., the contact region 212. Moreover, a dielectric layer stack is formed above the circuit element 210 and may be comprised of any appropriate dielectric material as is required for reliably insulating and passivating the circuit element 210. In one illustrative embodiment, a contact etch stop layer 202, for instance comprised of silicon nitride or any other appropriate material, may be provided, followed by an interlayer dielectric layer 203, which may be formed of one or more appropriate dielectric materials. In one illustrative embodiment, the dielectric layer 203 may be substantially comprised of silicon dioxide. Contact openings 204A, 204B may be formed in the dielectric layers 203 and 202, thereby providing a connection to the respective contact regions 211 and 212. In one illustrative embodiment, one or more of the contact regions 211 and 212 may be comprised of a highly conductive metal silicide, which, in one embodiment, may be provided in the form of nickel silicide.

Moreover, the semiconductor device 200 may be exposed in one illustrative embodiment, as illustrated, to a pretreatment 220 for preparing the contact regions 211 and 212 for the subsequent deposition of a barrier material. In one illustrative embodiment, the pretreatment 220 may comprise a plasma-based treatment on the basis of an inert species, such as argon, hydrogen, nitrogen and the like. For example, the pretreatment 220 may be performed on the basis of a plasma ambient, including argon and hydrogen, for efficiently removing contaminants from the exposed portions of the contact regions 211, 212 in a sputter-like process.

The semiconductor device 200 as shown in FIG. 2a may be formed in accordance with well-established techniques for forming circuit elements, such as the circuit element 210, on the basis of any appropriate crystalline, polycrystalline and amorphous semiconductor materials. In illustrative embodiments, the circuit element 210 may represent a circuit element of a highly advanced silicon-based semiconductor device, wherein minimum critical dimensions, such as a gate length, i.e., in FIG. 2a, the horizontal dimension of the gate electrode 211A including the contact region 211, may be 90 nm and less or even 50 nm and less for highly advanced devices. In some illustrative embodiments, the formation of the circuit element 210 may comprise advanced silicidation processes for providing the contact regions 211 and 212 in the form of a highly conductive metal silicide.

In one illustrative embodiment, at least some of the regions 212, 211 may be formed as nickel silicide regions, during which a chemical reaction is initiated between nickel and the underlying silicon-containing material, thereby creating a significant amount of nickel monosilicide, while substantially avoiding the formation of the less conductive nickel disilicide. During the formation of respective nickel silicide regions, a heat treatment may be performed to initiate the respective chemical reaction and to stabilize the corresponding phase of the nickel silicide. For example, in any subsequent process steps, a certain temperature should not be exceeded, such as approximately 400° C., so as to not unduly convert further nickel monosilicide into unwanted nickel disilicide, thereby compromising the overall conductivity of the contact regions 211 and 212. As will be described later, according to illustrative embodiments of the present invention, the subsequent process steps for forming highly conductive contact plugs in the contact openings 204A, 204B may be performed at a temperature of approximately 400° C. and significantly less.

After the formation of the circuit element 210, including the contact regions 211 and 212, the contact etch stop layer 202 and the interlayer dielectric material 203 may be deposited on the basis of well-established techniques, typically involving a CVD technique with or without a plasma-assisted deposition atmosphere. Thereafter, the contact openings 204A, 204B may be formed by photolithography and advanced etch techniques, wherein, depending on the design requirements, a width of the openings 204A, 204B may be of the same order of magnitude as the corresponding critical dimensions, i.e., the respective gate length of the circuit element 210. Thereafter, the device 200 may be exposed to the ambient of the pretreatment 220 to remove any etch byproducts that may have formed on the exposed portions of the contact regions 211 and 212.

FIG. 2b schematically shows the semiconductor device 200 after the completion of the pretreatment 220 with a first barrier layer 207 that may comprise, in one illustrative embodiment, tungsten and nitrogen. The first barrier layer 207 may have a thickness 207A that may be approximately 10 nm or less, and in illustrative embodiments may be approximately 5 nm and even less. For example, the first barrier layer 207 may represent, in one illustrative embodiment, a tungsten nitride layer (WN), wherein the stoichiometric ratio between tungsten and nitrogen may vary depending on the process conditions of a corresponding deposition process 230.

In one illustrative embodiment, the deposition process 230 for depositing the barrier layer 207 may be designed as a thermal ALD process, wherein a process temperature, i.e., the temperature of the substrate 201, and thus of the circuit element 210, is maintained at 400° C. and less, wherein, in one illustrative embodiment, the temperature of the substrate 201 is held at approximately 300° C. and even less. The deposition atmosphere of the process 230 may be established on the basis of tungsten hexafluorine (WF₆), boron hydride (B₂H₆) and ammonia (NH₃) as reagent gases. For example, in order to drive the surface saturated thermal ALD process, a specified dose of the gases may be introduced into the deposition atmosphere of the process 230 followed by a subsequent purge step, thereby obtaining a deposition rate of tungsten nitride of approximately 1.0-1.4 Å per each deposition step. Consequently, a highly controllable and conformal deposition of the first barrier layer 207 may be accomplished so that, contrary to conventional approaches, a very thin, yet highly continuous, layer may be obtained, even at critical portions, such as lower portions 204D of the contact opening 204A, extending up to approximately 20-100 nm.

In other embodiments, the first barrier layer 207 may be formed by any other appropriate deposition techniques, for instance, on the basis of CVD techniques, which may provide the required step coverage. In still other embodiments, the first barrier layer 207 may be formed on the basis of well-established CVD techniques for the deposition of tungsten, wherein the process 230 may further comprise a subsequent nitridation process, in which a nitrogen-containing plasma is established to introduce nitrogen into the previously deposited tungsten layer. In one illustrative embodiment, the pretreatment 220 (FIG. 2a) and the deposition process 230 are performed without breaking the vacuum condition maintained throughout the treatment 220 and the deposition process 230. For example, a deposition tool may be used that allows the generation of a corresponding plasma-based ambient for the cleaning process 220, wherein, afterwards, the deposition ambient of the process 230 may be established without contacting the precleaned semiconductor device 200 with ambient air to avoid any recontamination of the previously cleaned structure.

In one illustrative embodiment, the first barrier layer 207 may comprise tungsten, wherein the layer 207 may include at least one sub-layer formed of tungsten nitride. The contents of nitrogen within the tungsten nitride layer may be adjusted on the basis of corresponding deposition parameters of the process 230 as has been previously explained. More-over, the crystallinity of the layer 207 may be adjusted on the basis of deposition parameters and/or on the basis of any post-treatment performed after the deposition process 230.

FIG. 2c schematically shows the semiconductor device 200 during a further deposition process 231 for forming a second barrier layer 208, defining, in combination with the first barrier layer and any further optional layers (not shown), a barrier layer stack 215. In one illustrative embodiment, the second barrier layer 208 may be comprised of a conductive material that is appropriate for providing adhesion and diffusing blocking characteristics with respect to a highly conductive metal that is to be subsequently deposited. In one illustrative embodiment, the second barrier layer 208 may comprise tantalum and/or tantalum nitride, titanium, titanium nitride and the like, wherein the layer 208 may be comprised of two or more sub-layers. In one illustrative embodiment, the layer 208 is deposited as a substantially pure tantalum layer, wherein, due to the high uniformity of the previously deposited tungsten-based first barrier layer 207, the deposition uniformity for the layer 208 achieved during the deposition process 231 is less critical, since the layer 207, which reliably covers the surfaces of the contact openings 204A, 204B, also acts as an efficient diffusion barrier material for highly conductive metals, such as copper. Consequently, the deposition process 231 may be performed on the basis of well-established techniques, such as physical vapor deposition (PVD), sputter deposition and the like. For highly sophisticated applications, when the total thickness of a barrier layer comprised of the layers 207 and 208 needs to be provided as an extremely thin barrier layer having a total thickness of approximately 50 nm or significantly less, the second barrier layer 208 may also be deposited on the basis of ALD techniques, for which well-approved process recipes for tantalum and tantalum nitride are available and may be appropriately used. In still other embodiments, the deposition process 231 may comprise a deposition step in which an appropriate catalyst material, such as palladium, platinum, copper, cobalt and the like, may be deposited or incorporated into the barrier layer 208 to act as a catalyst during a subsequent electrochemical deposition process for forming a copper seed layer. During a corresponding deposition step for incorporating such a catalyst material, the coverage of exposed surfaces of the previously deposited material is less critical, since the catalyst material does not need to entirely cover the exposed surface portions.

In one illustrative embodiment, the layers 208 and 207 may be formed in an in situ process, thereby substantially avoiding any contact of the layer 207 after deposition with ambient air, which might lead to any oxidation of the layer 207.

FIG. 2d schematically shows the semiconductor device 200 in a further advanced manufacturing stage. Here, a seed layer 209 is formed on the barrier layer stack 215, which may, in this illustrative embodiment, be comprised of the first and second layers 207 and 208. The seed layer 209 may be formed by any appropriate deposition process 232, which may be, in one illustrative embodiment as previously described, an electrochemical process, such as an electroless plating process. In other embodiments, well-established sputter deposition techniques may be applied for forming the seed layer 209. Thereafter, a further deposition process may be performed, for instance, on the basis of well-established electrochemical deposition techniques, such as electroplating, to thereby fill the contact openings 204A, 204B in a highly non-conformal fashion, while substantially avoiding any void formation within the openings 204A and 204B. For example, in the damascene technique typically used for copper-based metallization layers, well-approved highly non-conformal electroplating techniques have been developed to fill even high aspect ratio vias with copper or copper alloys and these techniques may be adapted to be applicable to the contact openings 204A, 204B. During the electrochemical deposition of the copper or copper alloy, a certain degree of excess material may have to be deposited to reliably fill the contact openings 204A, 204B, which may then have to be removed by well-established techniques, such as electropolishing and chemical mechanical polishing (CMP). Electroless processes may also be performed to fill the openings 204A, 204B. In one illustrative embodiment, the excess material of the copper or copper alloy may be removed, along with the excess material of the layers 209, 208 and 207 formed on horizontal surface portions by a CMP process, during which the underlying dielectric layer 203 may act as a reliable CMP stop layer.

FIG. 2e schematically shows the semiconductor device 200 after the completion of the above-described process sequence. Hence, the device 200 comprises contact plugs 216A, 216B formed in the respective contact openings, which are comprised of the barrier layer stack 215, which may include the first barrier layer 207 and the second barrier layer 208. The layer 208 provides the desired adhesion and copper diffusion blocking capabilities and may be formed from tantalum-containing materials, such as tantalum, tantalum nitride and the like, wherein other materials, such as titanium, titanium nitride and the like may be used. The layers 207 and 208 may be provided with reduced thickness compared to conventional titanium nitride/titanium-based barrier layers for a tungsten-based contact plug, thereby significantly reducing the overall resistance of the plugs 216A, 216B. Furthermore, due to the highly conductive metal, such as copper or any alloys thereof, the series resistance of the plugs 216A, 216B, especially when high aspect ratio plugs are considered, is significantly reduced due to the enhanced thermal and electrical conductivity of copper and copper alloys compared to tungsten used in conventional techniques, while the barrier layer stack 215 provides high copper blocking efficiency.

FIG. 2f schematically shows the semiconductor device 200 according to still other illustrative embodiments. Here, the device 200 may be illustrated in a manufacturing stage after the deposition of a copper or a copper alloy layer 216 by, for instance, electroplating. The device 200 as shown may comprise a plurality of the circuit elements, such as the circuit elements 210, the contact openings of which are filled with respective copper or copper alloy plugs 216A, 216B. Moreover, the interlayer dielectric material of the layer 203 may have formed thereon a CMP stop layer 217, which may be configured such that it exhibits a superior diffusion blocking characteristic with respect to the copper-containing layer 216. For example, in one illustrative embodiment, the layer 217 may be comprised of silicon nitride, silicon carbide, nitrogen-enriched silicon carbide and the like. The CMP stop layer 217 may be provided to substantially prevent any contact of copper material with the interlayer dielectric layer 203 during a subsequent CMP process for removing the excess material of the copper layer 216. As previously explained, the barrier layer stack 215 may be provided comprising two or more sub-layers of extremely reduced thickness compared to conventional barrier layers, and, thus, during the CMP process for removing the excess copper or copper alloy, even minute amounts of copper may come into contact with the underlying interlayer dielectric material. For example, silicon dioxide is known to exhibit a moderately high copper diffusion which may be considered as inappropriate due to the close proximity of sensitive device regions of the circuit elements 210. Consequently, after forming the interlayer dielectric material 203, the layer 217 may be deposited, which may exhibit an excellent copper blocking capability, wherein, additionally, the layer 217 may exhibit an increased hardness, thereby avoiding substantial erosion of the dielectric material of the layer 203. As a consequence, the CMP process may be performed to efficiently remove the excess copper of the layer 216 while significantly reducing the incorporation of any copper into the interlayer dielectric material of the layer 203. Hence, the probability of incorporating copper atoms into sensitive device areas of the circuit elements 210 may be significantly reduced.

FIG. 2g schematically shows the semiconductor device 200 in accordance with yet another illustrative embodiment of the present invention. In this embodiment, the barrier layer stack 215 may comprise at least one additional layer 218, which may be formed on the dielectric material of the layer 203, thereby providing enhanced adhesion to the tungsten-based layer 207. In one illustrative embodiment, the layer 218 may be comprised of tungsten, which may be deposited by CVD or ALD, depending on process requirements. In one illustrative embodiment, the layers 218 and 207 may be formed in situ, wherein the corresponding precursor mixture may correspondingly be adjusted to deposit tungsten and thereafter tungsten nitride. In still other embodiments, the layers 218, 208 and 207 may be formed without breaking the vacuum condition, thereby substantially avoiding any oxidation of the layers 218 and 208. In some illustrative embodiments, the layer 218 may be substantially comprised of tungsten and may be deposited on the basis of sputter deposition techniques to provide an increased layer thickness at the bottom 204C of the contact openings 204A, 204B. Consequently, the stoichiometric ratio of the layer 207, deposited on the layer 218, may be correspondingly adjusted at the bottom 204C, thereby providing an enhanced interface with the lower-lying contact region 212, 211. In other embodiments, the layer 207 may be deposited in the form of a tungsten nitride layer on the basis of the previously described deposition techniques, while the layer 218, for instance comprised of tungsten, may be deposited on the layer 207, thereby providing a means for adjusting the stoichiometric ratio, especially at the bottom 204C. Thereafter, the deposition of the layer 208 may be performed, or, in other illustrative embodiments, the highly conductive material, such as copper or copper alloy, may be directly deposited without providing the layer 208.

As a result, the present invention provides an enhanced technique that enables the formation of contact plugs having a significantly increased conductivity compared to conventional tungsten-based contact plugs. For this purpose, a highly efficient copper blocking barrier layer is formed on the basis of tungsten and, in illustrative embodiments, on the basis of tungsten nitride, which may be deposited with excellent step coverage on the basis of appropriate deposition techniques, such as ALD, CVD and the like. Due to the provision of the tungsten-based barrier layer, a copper process sequence may be performed substantially without risking the diffusion of copper into sensitive device regions. Thus, in some illustrative embodiments, a tantalum-based barrier may be deposited, followed by a typical copper fill process, which may involve the deposition of a respective copper seed layer. During the formation of the tungsten-based barrier layer and the formation of optional further barrier layers and the filling in of the copper or copper alloy, process temperatures may be maintained at 400° C. and even less, for instance at 300° C., thereby substantially guaranteeing the thermal stability of any contact material provided in the circuit elements under consideration. For example, in illustrative embodiments, highly conductive metal silicides, such as nickel silicide, may be provided, wherein the thermal stability thereof may not be compromised during the subsequent process for forming the tungsten-containing barrier layer stack and the copper-based contact process sequence. Moreover, the contact process sequence is also compatible with any transistor architectures, such as SOI transistors, transistors having a raised drain and source region, transistors having one or more stress sources so as to create a corresponding strain in the channel regions thereof and the like. In addition, due to the atomic layer deposition technique that may be used for the formation of the tungsten-based barrier layer, the overall thickness of the barrier layer stack may be reduced, thereby additionally contributing to a reduced contact resistance. Furthermore, the enhanced deposition technique for a tungsten-based barrier layer provides the potential for further device scaling, since even contact plugs of high aspect ratio may be efficiently formed on the basis of the above-described techniques.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a transistor element having a contact region contacting one of a drain and source region; and
a contact plug formed in a dielectric layer so as to connect to said contact region, said contact plug comprising copper and a tungsten-containing barrier layer separating said dielectric layer and said contact plug.

2. The semiconductor device of claim 1, wherein said barrier layer comprises a first sub-layer comprised of tungsten and nitrogen.

3. The semiconductor device of claim 2, wherein said barrier layer comprises tantalum.

4. The semiconductor device of claim 3, wherein said tantalum is provided in a second sub-layer formed between said copper and said first sub-layer.

5. The semiconductor device of claim 4, wherein said second sub-layer is formed on said first sub-layer.

6. The semiconductor device of claim 2, wherein a thickness of said first sublayer is approximately 10 nm or less.

7. The semiconductor device of claim 6, wherein the thickness is approximately 5 nm or less.

8. The semiconductor device of claim 2, wherein said first sub-layer is formed on said dielectric layer.

9. The semiconductor device of claim 2, further comprising an adhesion layer formed on said dielectric layer and said contact region, wherein said first sub-layer is on said adhesion layer.

10. The semiconductor device of claim 1, wherein said contact region comprises nickel silicide.

11. A method, comprising:
forming a conductive barrier layer comprising tungsten in a contact opening of a transistor element on the basis of a tungsten-containing precursor material, said contact opening being in contact with one of a drain and source region; and
filling said contact opening with a copper-containing material.

12. The method of claim 11, wherein forming said conductive barrier layer comprises depositing a tungsten and nitrogen-containing layer.

13. The method of claim 13, further comprising depositing at least one further barrier material after depositing said tungsten and nitrogen-containing layer.

14. The method of claim 13, wherein said at least one further barrier material comprises tantalum.

15. The method of claim 13, further comprising depositing at least one further barrier material prior to depositing said tungsten and nitrogen-containing layer.

16. The method of claim 15, wherein a substrate temperature is maintained at approximately 400° C. or less when forming said conductive barrier layer.

17. The method of claim 11, further comprising forming a seed layer on said barrier layer and filling in said copper-containing material on the basis of an electrochemical deposition process.

18. The method of claim 11, wherein forming said conductive barrier layer comprises forming a tungsten nitride layer and forming a tantalum-comprising layer on said tungsten nitride layer.

19. The method of claim 18, wherein said tungsten nitride layer and said tantalum-comprising layer are formed without breaking a vacuum condition.

20. The method of claim 11, further comprising pretreating a contact region exposed in said contact opening prior to forming said conductive barrier layer.
